(19) United States
(12) Patent Application Publication
(10) Pub. No.: US 2025/0293669 A1
(43) Pub. Date: Sep. 18, 2025

(54) SIZE REDUCED ACOUSTIC WAVE FILTER DEVICE WITH PHASE CANCELLING CIRCUIT ELECTRICALLY CONNECTED WITH SHARED REFLECTOR

(71) Applicant: SKYWORKS SOLUTIONS, INC., Irvine, CA (US)

(72) Inventors: Rei Goto, Osaka-Shi (JP); Joji Fujiwara, Suita-Shi (JP); Kazuki Yamamura, Osaka-Shi (JP)

(21) Appl. No.: 19/076,061

(22) Filed: Mar. 11, 2025

Related U.S. Application Data
(60) Provisional application No. 63/564,116, filed on Mar. 12, 2024.

(51) Int. Cl. H03H 9/64; H03H 9/72

(52) U.S. Cl. CPC H03H 9/6489; H03H 9/643; H03H 9/725

(57) ABSTRACT

A first radio frequency filter and a second radio frequency filter disposed on a die, a first loop circuit disposed on the die, coupled to the first radio frequency filter, configured to generate a first anti-phase signal at a first frequency, and including a first signal line including a first reflector grating disposed between first interdigital transducer electrodes included in a first surface acoustic wave resonator of the first radio frequency filter and second of interdigital transducer electrodes included in a second surface acoustic wave resonator of the second radio frequency filter, and a second loop circuit disposed on the die, coupled to the second radio frequency filter, configured to generate a second anti-phase signal at a second frequency, and including a second signal line including a second reflector grating disposed between the first interdigital transducer electrodes and the second interdigital transducer electrodes.

### CROSS-REFERENCE TO RELATED APPLICATIONS

This application claims priority under 35 U.S.C. § 119 (e) to U.S. Provisional Patent Application Ser. No. 63/564,116, titled “SIZE REDUCED ACOUSTIC WAVE FILTER DEVICE WITH PHASE CANCELLING CIRCUIT ELECTRICALLY CONNECTED WITH SHARED REFLECTOR,” filed Mar. 12, 2024, the entire content of which is incorporated herein by reference for all purposes.

### BACKGROUND

### Technical Field

Embodiments of this disclosure relate to acoustic wave filters.

### Description of Related Technology

Acoustic wave filters can filter radio frequency signals. An acoustic wave filter can include a plurality of resonators arranged to filter a radio frequency signal. The resonators can be arranged as a ladder circuit. Example acoustic wave filters include surface acoustic wave (SAW) filters, bulk acoustic wave (BAW) filters, and Lamb wave resonator filters. A film bulk acoustic wave resonator filter is an example of a BAW filter. A solidly mounted resonator (SMR) filter is another example of a BAW filter.

Acoustic wave filters can be implemented in radio frequency electronic systems. For instance, filters in a radio frequency front end of a mobile phone can include acoustic wave filters. Two acoustic wave filters can be arranged as a duplexer.

### SUMMARY

In accordance with one aspect, there is provided an acoustic wave filter device. The acoustic wave filter device comprises a first radio frequency filter and a second radio frequency filter disposed on a die, each of the first radio frequency filter and the second radio frequency filter including a plurality of surface acoustic wave resonators with interdigital transducer electrodes and reflector gratings, a first loop circuit disposed on the die and coupled to the first radio frequency filter, the first loop circuit configured to generate a first anti-phase signal to a target signal at a first particular frequency, the first loop circuit including a first signal line, a portion of the first signal line including a first reflector grating disposed between first interdigital transducer electrodes included in a first surface acoustic wave resonator of the first radio frequency filter and second interdigital transducer electrodes included in a second surface acoustic wave resonator of the second radio frequency filter, and a second loop circuit disposed on the die and coupled to the second radio frequency filter, the second loop circuit configured to generate a second anti-phase signal to a target signal at a second particular frequency, the second loop circuit including a second signal line, a portion of the second signal line including a second reflector grating disposed between the first interdigital transducer electrodes and the second interdigital transducer electrodes.

In some embodiments, the first radio frequency filter forms part of a first duplexer, the first duplexer further including a third radio frequency filter, and the second radio frequency filter forms part of a second duplexer, the second duplexer further including a fourth radio frequency filter.

In some embodiments, a second portion of the first signal line includes a third reflector grating disposed between third interdigital transducer electrodes included in a third surface acoustic wave resonator of the third radio frequency filter and fourth interdigital transducer electrodes included in a fourth surface acoustic wave resonator of the fourth radio frequency filter.

In some embodiments, a second portion of the second signal line includes a fourth reflector grating disposed between the third interdigital transducer electrodes and the fourth interdigital transducer electrodes.

In some embodiments, the first loop circuit includes a second plurality of surface acoustic wave resonators configured to generate the first anti-phase signal and the second loop circuit includes a third plurality of surface acoustic wave resonators configured to generate the second anti-phase signal, the second plurality of surface acoustic wave resonators configured to generate a first acoustic wave signal travelling in a first direction, the third plurality of surface acoustic wave resonators configured to generate a second acoustic wave signal travelling in a second direction, the first direction and the second direction being offset from one another.

In some embodiments, the first loop circuit includes a second plurality of surface acoustic wave resonators configured to generate the first anti-phase signal and the second loop circuit includes a third plurality of surface acoustic wave resonators configured to generate the second anti-phase signal, the second plurality of surface acoustic wave resonators configured to generate a first acoustic wave signal travelling in a first direction, the third plurality of surface acoustic wave resonators configured to generate a second acoustic wave signal travelling in a second direction, the first direction and the second direction being co-linear.

In some embodiments, the acoustic wave filter device further comprises a conductive path coupled to ground and including a portion passing between the first interdigital transducer electrodes and the second interdigital transducer electrodes.

In some embodiments, the portion of the conductive path passing between the first interdigital transducer electrodes and the second interdigital transducer electrodes includes a third reflector grating.

In some embodiments, the third reflector grating is shared between the first surface acoustic wave resonator and the second surface acoustic wave resonator.

In some embodiments, the first reflector grating includes a first subgrating and a second subgrating electrically unconnected to the first subgrating, and the second reflector grating includes a third subgrating and a fourth subgrating electrically unconnected to the third subgrating.

In some embodiments, the third reflector grating is electrically unconnected to both the first reflector grating and the second reflector grating.

In some embodiments, the first reflector grating and the second reflector grating are shared between the first surface acoustic wave resonator and the second surface acoustic wave resonator.

In some embodiments, the acoustic wave filter device is included in a radio frequency module.

In some embodiments, the radio frequency module is included in a wireless communication device.

### BRIEF DESCRIPTION OF THE DRAWINGS

Embodiments of this disclosure will now be described, by way of non-limiting example, with reference to the accompanying drawings.

FIG. 1 illustrates circuitry layout of a die including two duplexers and phase cancelling circuits;

FIG. 2 illustrates circuitry layout of a die including two duplexers and phase cancelling circuits in which portions of signal lines of the phase cancelling circuits include reflector gratings used in resonator structures of the duplexers;

FIG. 3 illustrates circuitry layout of a die including two duplexers and phase cancelling circuits in which portions of signal lines of the phase cancelling circuits include reflector gratings used in resonator structures of the duplexers and in which resonators of the phase cancelling circuits have offset acoustic paths;

FIG. 4 illustrates circuitry layout of a die including two duplexers and phase cancelling circuits in which portions of signal lines of the phase cancelling circuits include reflector gratings used in resonator structures of the duplexers and in which a ground line is disposed between the two duplexers;

FIG. 5A is a schematic block diagram of a module that includes an antenna switch and duplexers;

FIG. 5B is a schematic block diagram of a module that includes a power amplifier, a switch, and duplexers;

FIG. 5C is a schematic block diagram of a module that includes power amplifier, a switch, duplexers, and an antenna switch; and

FIG. 6 is a schematic block diagram of a wireless communication device that includes duplexers.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Consumers continue to demand electronic devices with reduced form factors and/or with increased capabilities within a given form factor. Reducing the size of a semiconductor die or chip while retaining its functionality may allow manufactures to produce a greater number of die for a particular use at reduced cost. Accordingly, it has been found desirable to continue to reduce the size of layout of circuitry on a die to perform a given function. Additionally, by including circuits with different functionality on a single die, the number of die utilized in a device may be reduced and the overall size of the device may be reduced due to, for example, less space taken up by packaging for a greater rather than a fewer number of dic.

Modern wireless communications devices such as cellular telephones typically include multiple radio frequency filters that may be in the form of acoustic wave filters formed from multiple acoustic wave elements. An acoustic wave filter can include a loop circuit to cancel an unwanted frequency component. The loop circuit can enhance transmit/receive isolation and attenuation for a particular frequency range. The loop circuit can apply a signal having approximately the same amplitude and an opposite phase to a signal component to be canceled. Surface acoustic wave (SAW) loops circuits have been used to improve isolation and attenuation characteristics in SAW filters. Examples of loop circuits are described in, for example, U.S. Pat. Nos. 9,722,573, 10,404,234, 10,476,482,and 11,038,487, each of which is incorporated herein by reference.

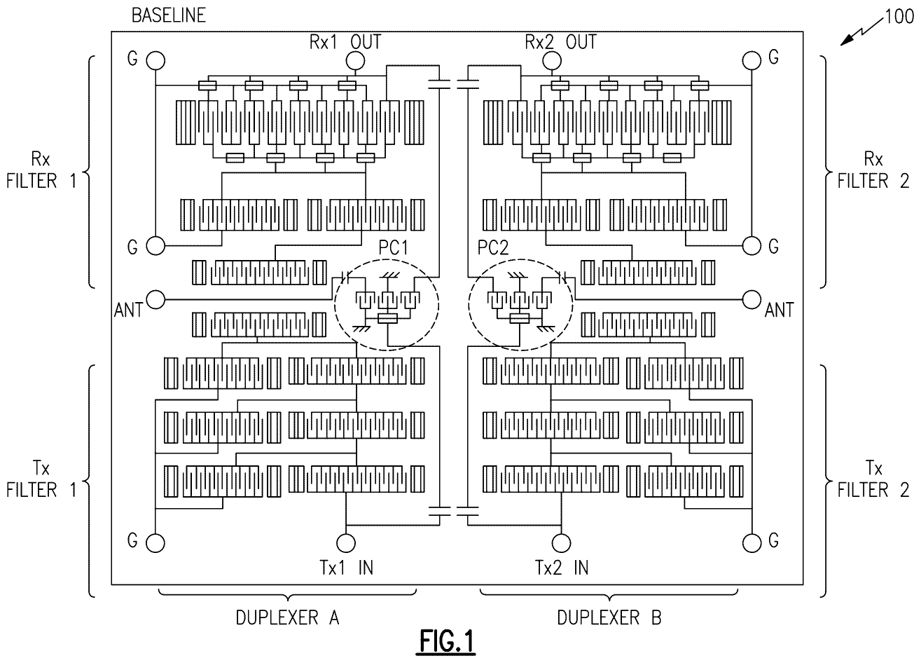

One example of a semiconductor die 100 including multiple circuit components is illustrated in FIG. 1. Die 100 includes two duplexers, Duplexer A and Duplexer B, that may operate in different frequency bands. Each of the duplexers includes a transmit filter (Tx Filter 1, Tx Filter 2) with respective transmission signal inputs Tx1 In, Tx2 In as well as a reception filter (Rx Filter 1, Rx Filter 2) with respective reception signal outputs Rx1 Out, Rx2 Out. Each of the transmit and receive filters are formed from groups of SAW resonators. The die 100 may include a multilayer piezoelectric substrate with the interdigital transducer electrodes and reflector gratings of the SAW resonators disposed on a layer of piezoelectric material (e.g., lithium niobate or lithium tantalate) on the upper surface of the substrate. The die 100 may alternatively include a temperature compensated SAW configuration in which the SAW resonators are covered with a layer of silicon dioxide or another dielectric material (not shown). Each of the duplexers also includes a phase cancelling loop circuit including groups of SAW resonators indicated at PCI and PC2, respectively, an antenna port Ant, and ground terminals G. In the semiconductor die 100 Duplexer A and Duplexer B are spaced apart from one another by an arca including signal lines for the phase cancelling loop circuits. In various embodiments disclosed herein different of the circuit elements may be combined in the space occupied by the signal lines, thus providing for the duplexers to be spaced closer together and reducing the overall die size.

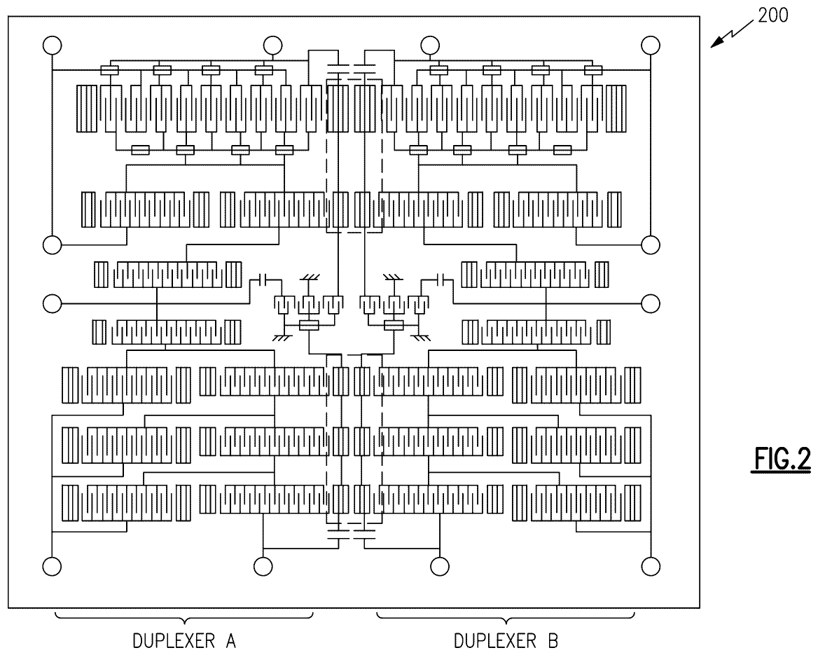

In one example, the innermost reflector gratings of the SAW resonators forming the duplexers may be utilized as portions of the signal lines for the phase cancelling loop circuits. This is shown in the die 200 of FIG. 2 in which the reflector gratings used as portions of the signal lines for the phase cancelling loop circuits are circled. These pairs of reflector gratings are also shared between the resonators on either side of them. In some embodiments, the pitch of the electrode fingers of the shared pair of reflectors is maintained such that the electrode fingers of the shared reflectors have the same pitch, including the pitch between the innermost adjacent electrode fingers of the pair of reflectors. All other circuit features of the die 200 are the same as those of die 100 and are not labelled in FIG. 2. Moving the innermost reflector gratings inward and using them as portions of the phase cancelling loop circuit signal lines eliminates the spacing between the innermost reflector gratings of the SAW resonators forming the duplexers and the phase cancelling loop circuit signal lines present in the example die 100 of FIG. 1, thereby reducing the die size. The die 200 may have a surface area reduced by about 4% as compared to the surface area of the die 100.

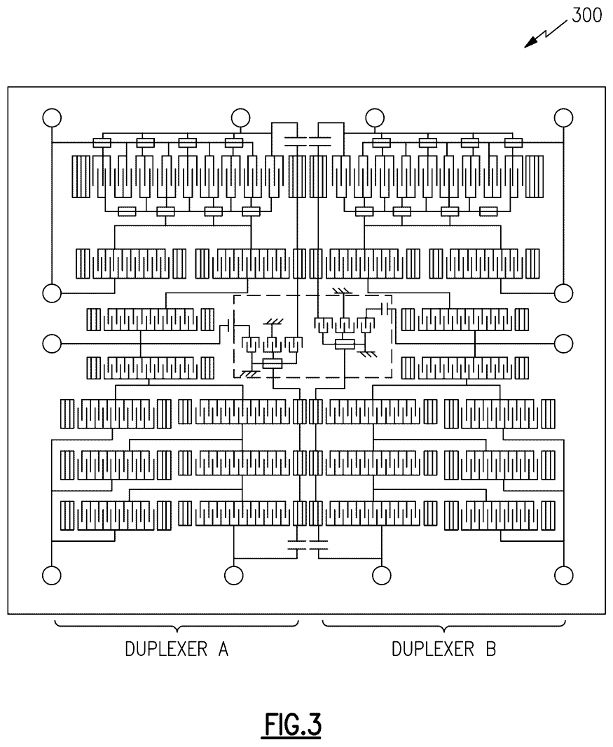

A variation of the die 200 of FIG. 2 is shown in FIG. 3, indicated generally at 300. In this die, the SAW resonators included in one of the phase cancelling loop circuits are offset from the SAW resonators included in the other of the phase cancelling loop circuits so that the directions in which the acoustic waves travel in the two groups of SAW resonators are offset and not co-linear. This may help avoid acoustic coupling between the two groups of SAW resonators and avoid generation of unwanted signals due to acoustic waves from one of the groups of SAW resonators travelling into the other.

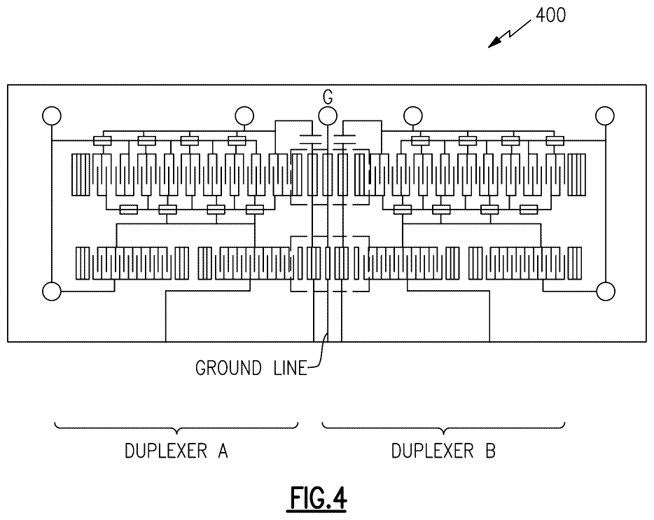

A further variation of the die 200 of FIG. 2 is shown in FIG. 4, indicated generally at 400 in which only an upper portion of the die is shown. In this die, the shared reflector gratings, circled in FIG. 4 are split into multiple sub-gratings. Five subgratings are shown for each of the shared reflectors are shown in FIG. 4 but in other embodiments three subgratings may be utilized. The subgratings are each electrically unconnected to one another. One of the subgratings in each set of shared reflector gratings is utilized as part of the signal line for the phase cancelling loop circuit of Duplexer A, a second one of the subgratings in each set of shared reflector gratings is utilized as part of the signal line for the phase cancelling loop circuit of Duplexer B, and a third one of the subgratings in each set of shared reflector gratings is included in a grounded conductive path. The grounded conductive path may be disposed centrally in the groups of subgratings between the subgratings used in the signal lines for the phase cancelling loop circuits as illustrated, although in other embodiments, different ones of the subgratings may be used in the grounded conductive path and in the signal lines for the phase cancelling loop circuits. The grounded conductive path may increase signal isolation between Duplexer A and Duplexer B while not adding significant area to the die because it passes through portions of reflector gratings that are already present.

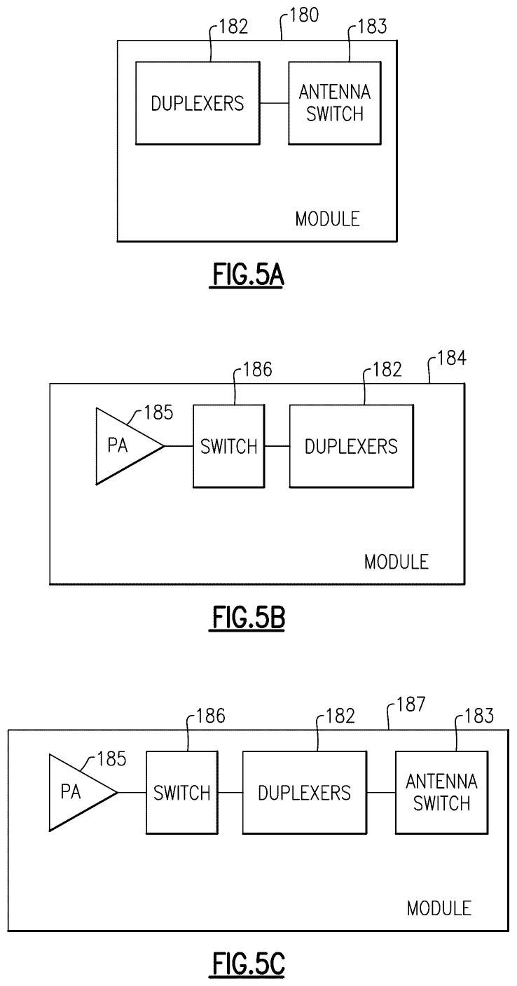

Die including acoustic wave filters and/or duplexers and loop circuits discussed herein can be implemented in a variety of packaged modules. Some example packaged modules will now be discussed in which any suitable principles and advantages of the reduced size die discussed herein can be implemented. FIGS. 5A, 5B, and 5C are schematic block diagrams of illustrative packaged modules according to certain embodiments.

FIG. 5A is a schematic block diagram of a module 180 that includes a die 182 having duplexers as disclosed herein and an antenna switch 183. The module 180 can include a package that encloses the illustrated elements. The duplexer die 182 and the antenna switch 183 can be disposed on the same packaging substrate. The packaging substrate can be a laminate substrate, for example. The duplexer die 182 can include duplexers and loop circuits including signal paths passing through reflector gratings of the resonators forming the duplexers in accordance with any suitable principles and advantages discussed herein. The antenna switch 183 can be a multi-throw radio frequency switch. The antenna switch 183 can selectively electrically couple a duplexer within the die 182 to an antenna port of the module 180.

FIG. 5B is a schematic block diagram of a module 184 that includes a power amplifier 185, a switch 186, and a duplexer die 182. The power amplifier 185 can amplify a radio frequency signal. The switch 186 can selectively electrically couple an output of the power amplifier 185 to a transmit port of the a duplexer within the duplexer die 182. The duplexers in the duplexer die 182 can include phase cancelling loop circuits in accordance with any suitable principles and advantages discussed herein.

FIG. 5C is a schematic block diagram of a module 187 that includes power amplifier 185, a switch 186, a duplexer die 182, and an antenna switch 183. The module 187 is similar to the module 184 of FIG. 5B, except the module 187 additionally includes the antenna switch 183.

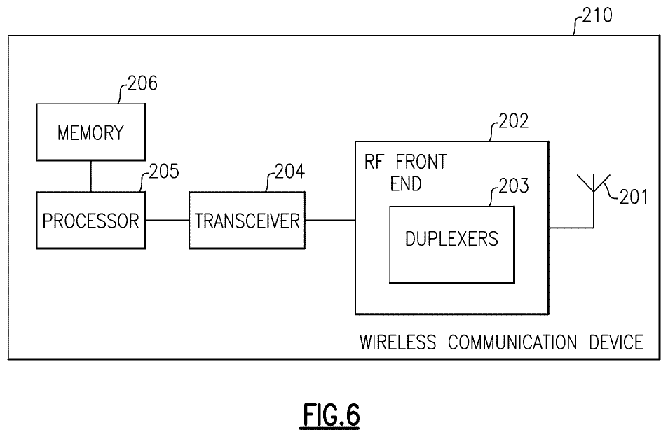

FIG. 6 is a schematic block diagram of a wireless communication device 200 that includes a duplexer die 203 in accordance with one or more embodiments. The wireless communication device 200 can be any suitable wireless communication device. For instance, a wireless communication device 200 can be a mobile phone, such as a smart phone. As illustrated, the wireless communication device 200 includes an antenna 201, an RF front end 202, an RF transceiver 204, a processor 205, and a memory 206. The antenna 201 can transmit RF signals provided by the RF front end 202. The antenna 201 can provide received RF signals to the RF front end 202 for processing.

The RF front end 202 can include one or more power amplifiers, one or more low noise amplifiers, RF switches, receive filters, transmit filters, duplex filters, filters of a multiplexer, filters of a diplexers or other frequency multiplexing circuit, or any suitable combination thereof. The RF front end 202 can transmit and receive RF signals associated with any suitable communication standards. Any of the duplexer die discussed herein can be implemented in the RF front end 202.

The RF transceiver 204 can provide RF signals to the RF front end 202 for amplification and/or other processing. The RF transceiver 204 can also process an RF signal provided by a low noise amplifier of the RF front end 202. The RF transceiver 204 is in communication with the processor 205. The processor 205 can be a baseband processor. The processor 205 can provide any suitable base band processing functions for the wireless communication device 200. The memory 206 can be accessed by the processor 205. The memory 206 can store any suitable data for the wireless communication device 200.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 300 GHz, such as in a range from about 450 MHz to 6 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, clements and/or states. Thus, such conditional language is not generally intended to imply that features, clements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An acoustic wave filter device comprising:
a first radio frequency filter and a second radio frequency filter disposed on a die, each of the first radio frequency filter and the second radio frequency filter including a plurality of surface acoustic wave resonators with interdigital transducer electrodes and reflector gratings;
a first loop circuit disposed on the die and coupled to the first radio frequency filter, the first loop circuit configured to generate a first anti-phase signal to a target signal at a first particular frequency, the first loop circuit including a first signal line, a portion of the first signal line including a first reflector grating disposed between first interdigital transducer electrodes included in a first surface acoustic wave resonator of the first radio frequency filter and second interdigital transducer electrodes included in a second surface acoustic wave resonator of the second radio frequency filter; and
a second loop circuit disposed on the die and coupled to the second radio frequency filter, the second loop circuit configured to generate a second anti-phase signal to a target signal at a second particular frequency, the second loop circuit including a second signal line, a portion of the second signal line including a second reflector grating disposed between the first interdigital transducer electrodes and the second interdigital transducer electrodes.

2. The acoustic wave filter device of claim 1 wherein the first radio frequency filter forms part of a first duplexer, the first duplexer further including a third radio frequency filter, and the second radio frequency filter forms part of a second duplexer, the second duplexer further including a fourth radio frequency filter.

3. The acoustic wave filter device of claim 2 wherein a second portion of the first signal line includes a third reflector grating disposed between third interdigital transducer electrodes included in a third surface acoustic wave resonator of the third radio frequency filter and fourth interdigital transducer electrodes included in a fourth surface acoustic wave resonator of the fourth radio frequency filter.

4. The acoustic wave filter device of claim 3 wherein a second portion of the second signal line includes a fourth reflector grating disposed between the third interdigital transducer electrodes and the fourth interdigital transducer electrodes.

5. The acoustic wave filter device of claim 1 wherein the first loop circuit includes a second plurality of surface acoustic wave resonators configured to generate the first anti-phase signal and the second loop circuit includes a third plurality of surface acoustic wave resonators configured to generate the second anti-phase signal, the second plurality of surface acoustic wave resonators configured to generate a first acoustic wave signal travelling in a first direction, the third plurality of surface acoustic wave resonators configured to generate a second acoustic wave signal travelling in a second direction, the first direction and the second direction being offset from one another.

6. The acoustic wave filter device of claim 1 wherein the first loop circuit includes a second plurality of surface acoustic wave resonators configured to generate the first anti-phase signal and the second loop circuit includes a third plurality of surface acoustic wave resonators configured to generate the second anti-phase signal, the second plurality of surface acoustic wave resonators configured to generate a first acoustic wave signal travelling in a first direction, the third plurality of surface acoustic wave resonators configured to generate a second acoustic wave signal travelling in a second direction, the first direction and the second direction being co-linear.

7. The acoustic wave filter device of claim 1 further comprising a conductive path coupled to ground and including a portion passing between the first interdigital transducer electrodes and the second interdigital transducer electrodes.

8. The acoustic wave filter device of claim 7 wherein the portion of the conductive path passing between the first interdigital transducer electrodes and the second interdigital transducer electrodes includes a third reflector grating.

9. The acoustic wave filter device of claim 8 wherein the third reflector grating is shared between the first surface acoustic wave resonator and the second surface acoustic wave resonator.

10. The acoustic wave filter device of claim 9 wherein the first reflector grating includes a first subgrating and a second subgrating electrically unconnected to the first subgrating, and the second reflector grating includes a third subgrating and a fourth subgrating electrically unconnected to the third subgrating.

11. The acoustic wave filter device of claim 9 wherein the third reflector grating is electrically unconnected to both the first reflector grating and the second reflector grating.

12. The acoustic wave filter device of claim 1 wherein the first reflector grating and the second reflector grating are shared between the first surface acoustic wave resonator and the second surface acoustic wave resonator.

13. A radio frequency module comprising the acoustic wave filter device claim 1.

14. A wireless communication device comprising the radio frequency module of claim 13.
